(19) United States
(12) Patent Application Publication
(10) Pub. No.: US 2026/0182068 A1
(43) Pub. Date: Jun. 25, 2026

(54) SOLID-STATE IMAGING DEVICE AND SEMICONDUCTOR DEVICE

(71) Applicant: SONY SEMICONDUCTOR SOLUTIONS CORPORATION, KANAGAWA (JP)

(72) Inventors: YUKI USHIKU, KANAGAWA (JP); KYOSUKE YAMADA, KANAGAWA (JP)

(21) Appl. No.: 19/124,636

(22) PCT Filed: Oct. 23, 2023
(86) PCT No.: PCT/JP2023/038168

§ 371 Date: Apr. 25, 2025

(30) Foreign Application Priority Data
Nov. 1, 2022 (JP) 2022-175753

(51) Int. Cl. H10F 39/00; H10F 39/12

(52) U.S. Cl. CPC H10F 39/811; H10F 39/199; H10F 39/802; H10F 39/8033; H10F 39/806; H10F 39/807

(57) ABSTRACT

Provided is a solid-state imaging device including a stacked structure in which a first substrate and a second substrate having a smaller area than the first substrate are stacked, the first substrate includes: an electronic circuit including an imaging element; an inspection circuit configured to inspect the electronic circuit; a first bonding electrode for electrical and physical bonding with the second substrate, the first bonding electrode being provided in a first stack region where the second substrate is to be stacked; and an inspection electrode provided in a region other than the first stack region and electrically connected to the inspection circuit, and the second substrate includes: a logic circuit that controls the imaging element; and a second bonding electrode for bonding with the first bonding electrode of the first substrate.

### FIELD

The present disclosure relates to a solid-state imaging device and a semiconductor device.

### BACKGROUND

For example, in manufacture of a semiconductor device such as a solid-state imaging device, a wafer and a chip are bonded and stacked. In such a case, it is possible to improve the yield of semiconductor devices by inspecting whether electronic circuits provided on wafers and chips are non-defective in advance and selectively stacking a non-defective wafer and a non-defective chip. An example of an inspection circuit for performing such inspection is an inspection circuit described in Patent Literature 1 below.

### CITATION LIST

### Patent Literature

Patent Literature 1: JP 2021-103760 A

### SUMMARY

### Technical Problem

Therefore, the inspection is performed by bringing a probe tip of an inspection device into contact with an inspection electrode provided on a wafer before the stacking as described above is performed, but the probe tip sometimes leaves a probe mark having irregularities on the inspection electrode of an inspection circuit. Then, in a case where a non-defective chip is to be bonded and stacked onto the inspection electrode having such a probe mark, since the probe mark has the irregularities, there is a high probability that a bonding failure occurs between the wafer and the chip.

Therefore, the present disclosure proposes a solid-state imaging device and a semiconductor device capable of avoiding occurrence of a bonding failure between a wafer (or chip) and a chip due to a probe mark left on an inspection electrode.

### Solution to Problem

According to the present disclosure, there is provided a solid-state imaging device including a stacked structure in which a first substrate and a second substrate having a smaller area than the first substrate are stacked. In the solid-state imaging device, the first substrate includes: an electronic circuit including an imaging element; an inspection circuit configured to inspect the electronic circuit; a first bonding electrode for electrical and physical bonding with the second substrate, the first bonding electrode being provided in a first stack region where the second substrate is to be stacked; and an inspection electrode provided in a region other than the first stack region and electrically connected to the inspection circuit, and the second substrate includes: a logic circuit that controls the imaging element; and a second bonding electrode for bonding with the first bonding electrode of the first substrate.

Furthermore, according to the present disclosure, there is provided a semiconductor device including a stacked structure in which a first substrate and a second substrate having a smaller area than the first substrate are stacked. In the semiconductor device, the first substrate includes: an electronic circuit; an inspection circuit configured to inspect the electronic circuit; a first bonding electrode for electrical and physical bonding with the second substrate, the first bonding electrode being provided in a first stack region where the second substrate is to be stacked; and an inspection electrode provided in a region other than the first stack region and electrically connected to the inspection circuit, and the second substrate includes a second bonding electrode for bonding with the first bonding electrode of the first substrate.

### BRIEF DESCRIPTION OF DRAWINGS

FIG. 1 is a block diagram illustrating an outline of a basic configuration of a CMOS image sensor which is an example of an imaging device applicable to each of embodiments of the present disclosure.

FIG. 2 is a circuit diagram illustrating an example of a circuit configuration of a pixel applicable to each of the embodiments of the present disclosure.

FIG. 3 is a block diagram illustrating an example of a configuration of a column-parallel AD conversion unit applicable to each of the embodiments of the present disclosure.

FIG. 4 is an exploded perspective view illustrating an outline of a stacked chip structure of the imaging device.

FIG. 5 is a diagram illustrating a specific configuration example of a first semiconductor substrate of the imaging device to which the technology of the present disclosure can be applied.

FIG. 6 is a diagram illustrating a specific configuration example of a configuration of the first semiconductor substrate of the imaging device to which the technology of the present disclosure can be applied.

FIG. 7 is an explanatory view (Part 1) for describing a manufacturing method of an imaging device according to a first embodiment of the present disclosure.

FIG. 8 is an explanatory view (Part 2) for describing the manufacturing method of the imaging device according to the first embodiment of the present disclosure.

FIG. 9 is an explanatory view (Part 3) for describing the manufacturing method of the imaging device according to the first embodiment of the present disclosure.

FIG. 10 is an explanatory view (Part 4) for describing the manufacturing method of the imaging device according to the first embodiment of the present disclosure.

FIG. 11 is an explanatory view (Part 5) for describing the manufacturing method of the imaging device according to the first embodiment of the present disclosure.

FIG. 12 is an explanatory view for describing the imaging device according to the first embodiment of the present disclosure.

FIG. 13 is an explanatory view for describing an imaging device according to a second embodiment of the present disclosure.

FIG. 14 is an explanatory view for describing an imaging device according to a third embodiment of the present disclosure.

FIG. 15 is an explanatory view for describing a manufacturing method of an imaging device according to a fourth embodiment of the present disclosure.

FIG. 16 is an explanatory view illustrating the imaging device according to the fourth embodiment of the present disclosure.

FIG. 17 is a view illustrating application examples using each of the embodiments according to the technology of the present disclosure.

FIG. 18 is a block diagram illustrating a configuration of an example of a camera to which the technology according to the present disclosure can be applied.

### DESCRIPTION OF EMBODIMENTS

Hereinafter, preferred embodiments of the present disclosure will be described in detail with reference to the accompanying drawings. Note that constituent elements having substantially the same functional configuration in the present specification and the drawings will be denoted by the same reference sign, and the redundant description thereof will be omitted. In addition, in the present specification and the drawings, a plurality of constituent elements having substantially the same or similar functional configuration may be distinguished from each other by the same reference sign followed by different numerals or alphabets. However, in a case where there is no need to particularly distinguish each of the plurality of constituent elements having substantially the same or similar functional configuration, the same reference sign alone will be attached.

In addition, the drawings referred to in the following description are drawings for facilitating the description and understanding of an embodiment of the present disclosure, and shapes, dimensions, ratios, and the like illustrated in the drawings are sometimes different from actual ones for the sake of clarity. Furthermore, a device and the like illustrated in the drawings can be appropriately modified in design in consideration of the following description and known techniques.

Furthermore, in the following description, “electrically connecting” means connecting a plurality of elements directly or indirectly via other elements.

Note that the description will be given in the following order.
1. Background to Creation of Embodiments of Present Disclosure
1.1 Configuration Example of CMOS Image Sensor
1.2 Example of Circuit Configuration of Pixel
1.3 Configuration Example of Column-Parallel Analog-to-Digital Conversion Unit
1.4 Example of Stacked Structure
1.5 Outline of Inspection
1.6 Configuration Example of Inspection Circuit
1.7 Background
2. First Embodiment
2.1 Manufacturing Method
2.2 Detailed Structure
3. Second Embodiment
4. Third Embodiment
5. Fourth Embodiment
5.1 Manufacturing Method
5.2 Detailed Structure
6. Summary
7. Application Examples
8. Supplement

### 1. Background to Creation of Embodiments of Present Disclosure

First, a background leading to creation of embodiments of the present disclosure by the present inventors will be described before describing the embodiments of the present disclosure. First, a schematic configuration of an imaging device (solid-state imaging device) to which the technology of the present disclosure can be applied will be sequentially described.

### <1.1 Configuration Example of CMOS Image Sensor>

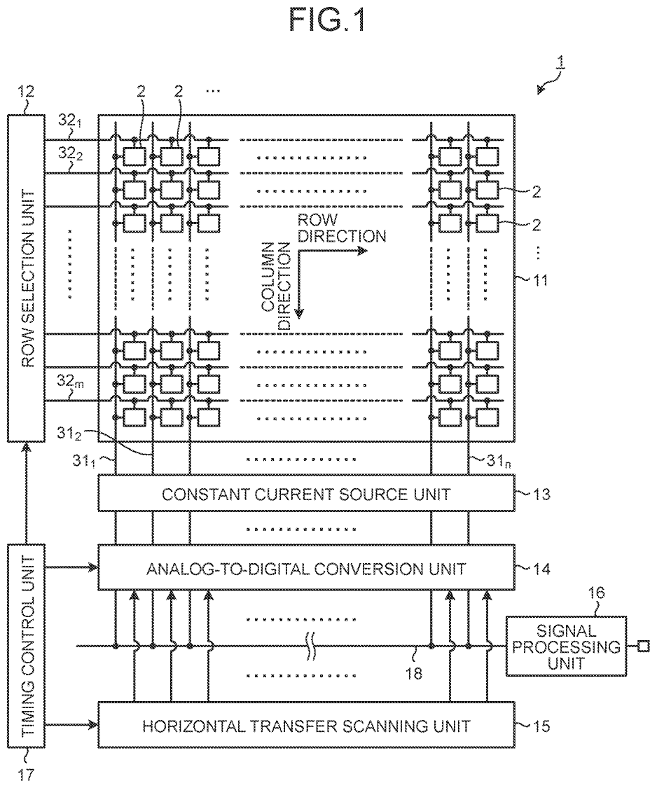

First, a basic configuration of an imaging device 1 to which the technology of the present disclosure can be applied will be described. Here, as the imaging device 1, a complementary metal oxide semiconductor (CMOS) image sensor, which is a type of an imaging device of an XY address scheme, will be described as an example. The CMOS image sensor is an image sensor fabricated by applying or partially using a CMOS process. FIG. 1 is a block diagram illustrating an outline of a basic configuration of the CMOS image sensor which is an example of the imaging device 1 applicable to each of the embodiments of the present disclosure.

The imaging device 1 illustrated in FIG. 1 includes a pixel array unit (cell array) 11 in which pixels (cells) (imaging elements) 2 each including a photoelectric conversion unit are two-dimensionally arranged in a row direction and a column direction, that is, in a matrix array, and a peripheral circuit unit of the pixel array unit 11. Here, the row direction refers to an arrangement direction (horizontal direction) of the pixels 2 in a pixel row, and the column direction refers to an arrangement direction (vertical direction) of the pixels 2 in a pixel column. The pixel 2 performs photoelectric conversion to generate and accumulate a charge corresponding to the amount of received light.

In the example of FIG. 1, examples of the peripheral circuit unit of the pixel array unit 11 include a row selection unit 12, a constant current source unit 13, an analog-to-digital conversion unit 14, a horizontal transfer scanning unit 15, a signal processing unit 16, and a timing control unit 17.

In the pixel array unit 11, control lines 32₁ to 32ₙ are wired along the row direction for pixel rows, respectively, with respect to the matrix-like pixel array. In addition, vertical signal lines 31₁ to 31ₘ are wired along the column direction for pixel columns, respectively. Note that, in a case where there is no need to particularly distinguish the vertical signal lines 31₁ to 31ₘ, the vertical signal lines 31₁ to 31ₘ will be described as the vertical signal lines 31 as appropriate. Similarly, in a case where there is no need to particularly distinguish the control lines 32₁ to 32ₙ, the control lines 32₁ to 32ₙ will be described as the control lines 32 as appropriate.

The control line 32 transmits a drive signal for performing driving when a signal is read from the pixel 2. In FIG. 1, the control line 32 is illustrated as one wire, but the control line 32 is not limited to one, and may include a plurality of wires. One end of the control line 32 is connected to an output end corresponding to each row of the row selection unit 12.

Next, each circuit portion of the peripheral circuit unit of the pixel array unit 11, that is, the row selection unit 12, the constant current source unit 13, the analog-to-digital conversion unit 14, the horizontal transfer scanning unit 15, the signal processing unit 16, and the timing control unit 17 will be described.

The row selection unit 12 includes a shift register, an address decoder, and the like, and controls scanning of a pixel row and an address of the pixel row in selecting each of the pixels 2 included in the pixel array unit 11. Although a specific configuration of the row selection unit 12 is not illustrated, the row selection unit 12 generally includes two scanning systems of a read scanning system and a sweep scanning system.

The read scanning system selectively scans the pixels 2 of the pixel array unit 11 in units of rows in order to read pixel signals from the pixels 2. The pixel signals read from the pixels 2 are analog signals. The sweep scanning system performs sweep scanning on a read row on which read scanning is performed by the read scanning system prior to the read scanning by a time corresponding to a shutter speed.

With the sweep scanning performed by the sweep scanning system, unnecessary charges are swept from the photoelectric conversion units of the pixels 2 in the read row, whereby the photoelectric conversion units are reset. Then, since the unnecessary charges are swept (reset) by the sweep scanning system, a so-called electronic shutter operation is performed. Here, the electronic shutter operation refers to an operation of discarding the charges of the photoelectric conversion units and newly starting exposure (starting accumulation of charges).

The constant current source unit 13 includes a plurality of current sources I each including, for example, a metal oxide semiconductor (MOS) transistor and connected to the vertical signal lines 31₁ to 31ₘ for the pixel columns, respectively. The constant current source unit 13 supplies a bias current to each of the pixels 2 of the pixel row selectively scanned by the row selection unit 12 through each of the vertical signal lines 31₁ to 31ₘ.

The analog-to-digital conversion unit 14 includes, for example, a plurality of analog-to-digital converters provided for the pixel columns, respectively, and provided to correspond to the pixel columns, respectively, of the pixel array unit 11. The analog-to-digital conversion unit 14 is a column-parallel analog-to-digital conversion unit that converts a pixel signal, which is an analog signal output through each of the vertical signal lines 31₁ to 31ₘ for each pixel column, into an N-bit digital signal. Hereinafter, the analog-to-digital conversion unit 14 is referred to as a column-parallel analog-to-digital conversion unit 14.

As the analog-to-digital converter included in the column-parallel analog-to-digital conversion unit 14, for example, a single-slope analog-to-digital converter that is an example of a reference signal comparison analog-to-digital converter can be used. Note that the present disclosure is not limited to such an example, and a successive approximation analog-to-digital converter, a delta-sigma modulation (42 modulation) analog-to-digital converter, or the like can be used as the analog-to-digital converter included in the column-parallel analog-to-digital conversion unit 14.

The horizontal transfer scanning unit 15 includes a shift register, an address decoder, and the like, and controls scanning of a pixel column and an address of the pixel column in reading a signal of each of the pixels 2 of the pixel array unit 11. Under the control of the horizontal transfer scanning unit 15, the pixel signal converted into the digital signal by the column-parallel analog-to-digital conversion unit 14 is read to a horizontal transfer line 18 having a width of 2 N bits in units of pixel columns.

The signal processing unit 16 performs predetermined signal processing on the digital pixel signal supplied through the horizontal transfer line 18 to generate two-dimensional image data. For example, the signal processing unit 16 can perform each signal processing such as correction of a vertical line defect and a point defect, and signal clamping on the supplied pixel signal. In addition, the signal processing unit 16 can perform signal processing such as parallel-to-serial conversion, compression, encoding, addition, averaging, and intermittent operation on the supplied pixel signal. The signal processing unit 16 outputs the generated image data to a subsequent device as an output signal of the imaging device 1.

The timing control unit 17 generates various timing signals, clock signals, control signals, and the like, and performs drive control of the row selection unit 12, the constant current source unit 13, the column-parallel analog-to-digital conversion unit 14, the horizontal transfer scanning unit 15, the signal processing unit 16, and the like based on the generated signals.

### <1.2 Example of Circuit Configuration of Pixel>

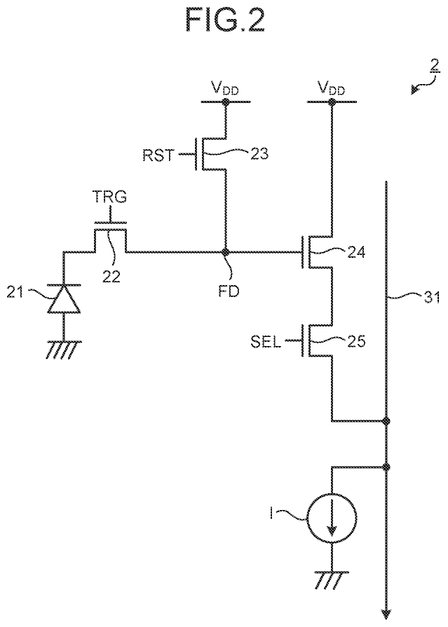

FIG. 2 is a circuit diagram illustrating an example of a circuit configuration of the pixel 2 applicable to each of the embodiments of the present disclosure. The pixel 2 includes, for example, a photodiode 21 as the photoelectric conversion unit. The pixel 2 includes a transfer transistor 22, a reset transistor 23, an amplification transistor 24, and a selection transistor 25 in addition to the photodiode 21.

In the example of FIG. 2, the four transistors of the transfer transistor 22, the reset transistor 23, the amplification transistor 24, and the selection transistor 25 are formed using, for example, N-channel MOS field effect transistors (FETs). Hereinafter, the N-channel MOS field effect transistor is referred to as an NMOS transistor. Since the pixel 2 includes only the NMOS transistors, it is possible to achieve optimization from the viewpoint of area efficiency and process reduction. Note that a combination of conductivity types of the transfer transistor 22, the reset transistor 23, the amplification transistor 24, and the selection transistor 25 illustrated in FIG. 2 is merely an example, and the combination thereof is not limited.

For the pixel 2, as the above-described control line 32, a plurality of control lines are wired in common to each of the pixels 2 of the same pixel row. The plurality of control lines are connected to the output end corresponding to each of the pixel rows of the row selection unit 12 in units of the pixel rows. The row selection unit 12 appropriately outputs a transfer signal TRG, a reset signal RST, and a selection signal SEL to the plurality of control lines.

The photodiode 21 has an anode electrode connected to a low-potential-side power supply (for example, a ground potential), photoelectrically converts received light into a charge (here, photoelectrons) having a charge amount corresponding to the amount of the light, and accumulates the charge. A cathode electrode of the photodiode 21 is electrically connected to a gate electrode of the amplification transistor 24 via the transfer transistor 22. Here, a region electrically connected to the gate electrode of the amplification transistor 24 is a floating diffusion region FD. The floating diffusion region FD is a charge-to-voltage conversion unit that converts a charge into a voltage.

The transfer signal TRG which is active at a high level (for example, VDD level) is supplied from the row selection unit 12 to a gate electrode of the transfer transistor 22. The transfer transistor 22 becomes conductive in response to the transfer signal TRG, thereby transferring the charge, photoelectrically converted by the photodiode 21 and accumulated in the photodiode 21, to the floating diffusion region FD.

The reset transistor 23 is connected between a node of a power supply VDD that supplies a high-potential-side power supply voltage and the floating diffusion region FD. The reset signal RST which is active at a high level is supplied from the row selection unit 12 to a gate electrode of the reset transistor 23. The reset transistor 23 becomes conductive in response to the reset signal RST, and discards the charge of the floating diffusion region FD to the node of the power supply VDD to reset the floating diffusion region FD.

The gate electrode and a drain electrode of the amplification transistor 24 are connected to the floating diffusion region FD and the node of the power supply VDD, respectively. The amplification transistor 24 serves as an input unit of a source follower that reads a signal obtained by photoelectric conversion in the photodiode 21. That is, a source electrode of the amplification transistor 24 is connected to the vertical signal line 31 via the selection transistor 25. Then, the amplification transistor 24 and the current source I connected to one end of the vertical signal line 31 constitute the source follower that converts the voltage of the floating diffusion region FD into a voltage of the vertical signal line 31.

A drain electrode and a source electrode of the selection transistor 25 are connected to the source electrode of the amplification transistor 24 and the vertical signal line 31, respectively. The selection signal SEL which is active at a high level is supplied from the row selection unit 12 to a gate electrode of the selection transistor 25. The selection transistor 25 becomes conductive in response to the selection signal SEL, thereby transmitting a signal output from the amplification transistor 24 to the vertical signal line 31 with the pixel 2 in a selected state.

Note that, as for the selection transistor 25, a circuit configuration connected between the node of the power supply VDD and the drain electrode of the amplification transistor 24 can also be applied. In addition, in the example of FIG. 2, a 4Tr configuration including the four transistors (Tr), that is, the transfer transistor 22, the reset transistor 23, the amplification transistor 24, and the selection transistor 25, has been described as an example of a pixel circuit of the pixel 2, but the present disclosure is not limited thereto. For example, it is possible to adopt a 3Tr configuration in which the selection transistor 25 is omitted and the amplification transistor 24 has the function of the selection transistor 25, or to adopt a configuration of 5Tr or more obtained by increasing the number of transistors as necessary.

### <1.3 Configuration Example of Column-Parallel Analog-to-Digital Conversion Unit>

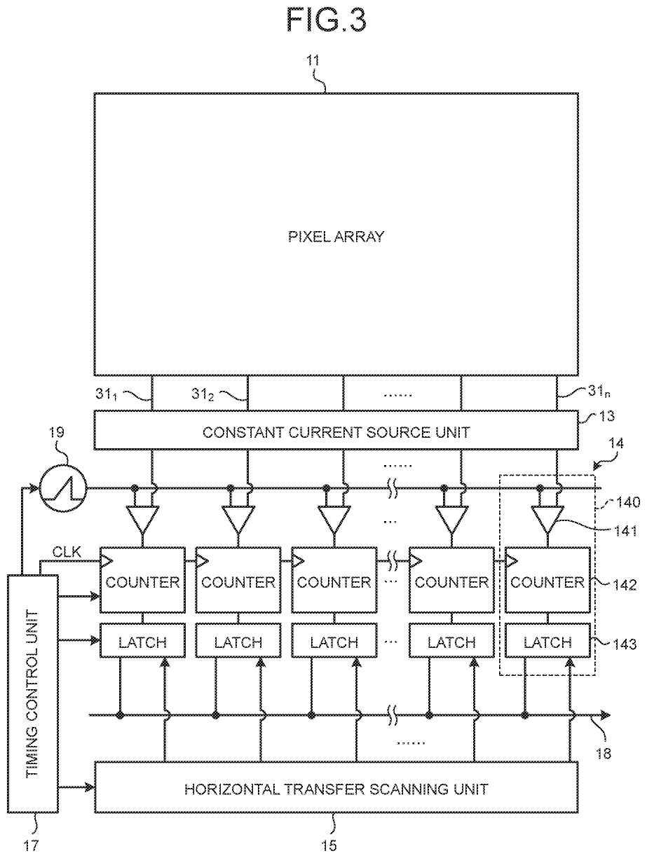

Next, a configuration example of the column-parallel analog-to-digital conversion unit 14 will be described. FIG. 3 is a block diagram illustrating an example of a configuration of the column-parallel analog-to-digital conversion unit 14 applicable to each of the embodiments of the present disclosure. The analog-to-digital conversion unit 14 in the imaging device 1 of the present disclosure includes a set of a plurality of single-slope analog-to-digital converters provided to correspond to the vertical signal lines 31₁ to 31ₘ, respectively. Here, a single-slope analog-to-digital converter 140 of the nth column will be described as an example.

The single-slope analog-to-digital converter 140 has a circuit configuration including a comparator 141, a counter circuit 142, and a latch circuit 143. The single-slope analog-to-digital converter 140 uses a reference signal of a so-called RAMP waveform (slope waveform) in which a voltage value linearly changes with time. The reference signal of the ramp waveform is generated by a reference signal generation unit 19. The reference signal generation unit 19 can be configured using, for example, a digital-to-analog conversion circuit.

The comparator 141 uses the analog pixel signal read from the pixel 2 as a comparison input and the reference signal of the ramp waveform generated by the reference signal generation unit 19 as a reference input, and compares both the signals. Then, for example, an output of the comparator 141 is a first state (for example, high level) when the reference signal is larger than the pixel signal, and is a second state (for example, low level) when the reference signal is equal to or smaller than the pixel signal. As a result, the comparator 141 outputs, as a comparison result, a pulse signal having a pulse width corresponding to a signal level of the pixel signal, specifically, a magnitude of the signal level.

A clock signal CLK is provided from the timing control unit 17 to the counter circuit 142 at the same timing as a supply start timing of the reference signal with respect to the comparator 141. Then, the counter circuit 142 performs a count operation in synchronization with the clock signal CLK to measure a period of the pulse width of the output pulse of the comparator 141, that is, a period from the start of a comparison operation to the end of the comparison operation. A count result (count value) of the counter circuit 142 is a digital value obtained by digitizing the analog pixel signal.

The latch circuit 143 holds (latches) the digital value which is the count result of the counter circuit 142. In addition, the latch circuit 143 obtains a difference between a count value of a D-phase corresponding to a pixel signal at the signal level and a count value of a P-phase corresponding to a pixel signal at a reset level, thereby performing correlated double sampling (CDS) which is an example of noise removal processing. Then, the latch circuit 143 outputs the latched digital value to the horizontal transfer line 18 under driving by the horizontal transfer scanning unit 15.

As described above, in the column-parallel analog-to-digital conversion unit 14 including the set of single-slope analog-to-digital converters 140, the digital value is obtained from time information until the magnitude relationship between the reference signal, which is a linearly changing analog value generated by the reference signal generation unit 19, and the analog pixel signal output from the pixel 2 changes. Note that the single-slope analog-to-digital conversion unit 14 in which the analog-to-digital converters 140 are arranged in a one-to-one relationship with the pixel columns has been exemplified in the above example, but the analog-to-digital conversion unit 14 in which the single-slope analog-to-digital converters 140 are arranged in units of a plurality of pixel columns can also be adopted.

### <1.4 Example of Stacked Structure>

Next, an example of a stacked structure of the CMOS image sensor as the imaging device 1 having the above-described configuration will be described. The imaging device 1 having the above-described configuration has a stacked chip structure (stacked chip).

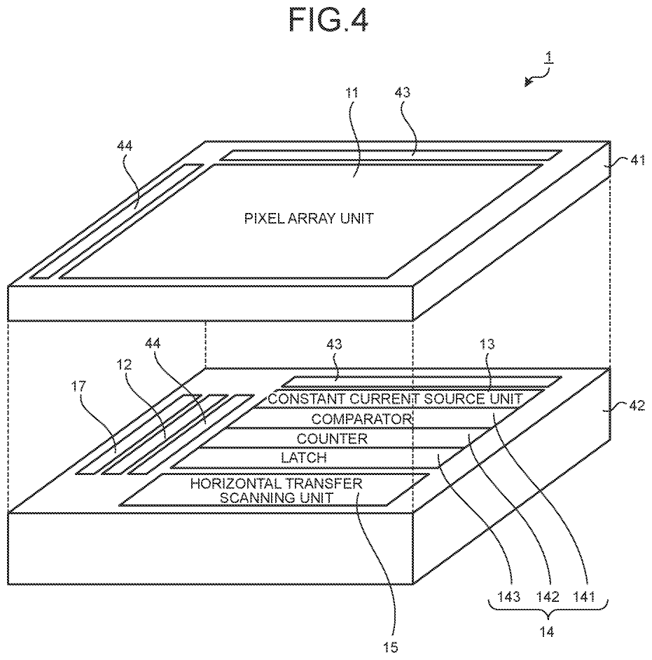

FIG. 4 is an exploded perspective view illustrating an outline of the stacked chip structure of the imaging device 1. Note that a first semiconductor substrate 41 and a second semiconductor substrate 42 are illustrated in the same size in FIG. 4, but the size of the second semiconductor substrate 42 may be actually smaller than that of the first semiconductor substrate 41 in the imaging device 1 applied in the embodiments of the present disclosure.

As illustrated in FIG. 4, the stacked chip structure of the imaging device 1 has a structure in which at least two semiconductor substrates of the first semiconductor substrate 41 and the second semiconductor substrate 42 are stacked and bonded. In this stacked structure, each of the pixels 2 of the pixel array unit 11, the control lines 32₁ to 32ₙ, and the vertical signal lines 31₁ to 31ₘ are formed on the first semiconductor substrate 41 of the first layer.

In addition, on the second semiconductor substrate 42 of the second layer, a pixel control unit including the row selection unit 12, the constant current source unit 13, the analog-to-digital conversion unit 14, the horizontal transfer scanning unit 15, the signal processing unit 16, the timing control unit 17, the reference signal generation unit 19, and the like is formed. Note that, in FIG. 4, the signal processing unit 16 and the reference signal generation unit 19 are omitted in order to avoid complexity. The pixel control unit is a peripheral circuit unit of the pixel array unit 11.

Then, the first semiconductor substrate 41 of the first layer and the second semiconductor substrate 42 of the second layer are electrically connected by connecting portions 43 and 44 such as a through chip via (TCV) and Cu—Cu hybrid bonding.

According to such a stacked structure, since the area can be made as large as the pixel array unit 11 can be formed as the first semiconductor substrate 41 of the first layer, the size of the first semiconductor substrate 41 and the entire chip size can be reduced. Furthermore, a process suitable for fabricating the pixels 2 can be applied to the first semiconductor substrate 41 of the first layer, and a process suitable for fabricating the pixel control unit can be applied to the second semiconductor substrate 42 of the second layer, and thus the processes can be optimized in manufacturing the imaging device 1.

Note that the stacked structure, which is a two-layer structure formed by stacking the first semiconductor substrate 41 and the second semiconductor substrate 42, has been exemplified here, but the stacked structure is not limited to the two-layer structure, and can also be a structure of three or more layers.

### <1.5 Outline of Inspection>

In sorting a non-defective product and a defective product of the imaging device 1, presence or absence of opening (breakage) of wires such as the control lines 32₁ to 32ₙ and the vertical signal lines 31₁ to 31ₘ and presence or absence of short (short circuit) between adjacent wires are generally inspected.

Meanwhile, examples of a stacking scheme of a stacked chip include a scheme (WOW: wafer on wafer) of bonding a wafer and a wafer together and a scheme (COW: chip on wafer) of bonding a wafer and a non-defective chip together. In the case of a stacked chip of the COW scheme, unlike the case of a stacked chip of the WOW scheme, the yield can be increased by selectively combining a non-defective product and a non-defective product.

Therefore, in the imaging device 1 to which the present disclosure can be applied, an inspection circuit is added to the first semiconductor substrate 41, which is a sensor substrate on which the pixel array unit 11 is formed, to implement the inspection of presence or absence of opening/short of the wires.

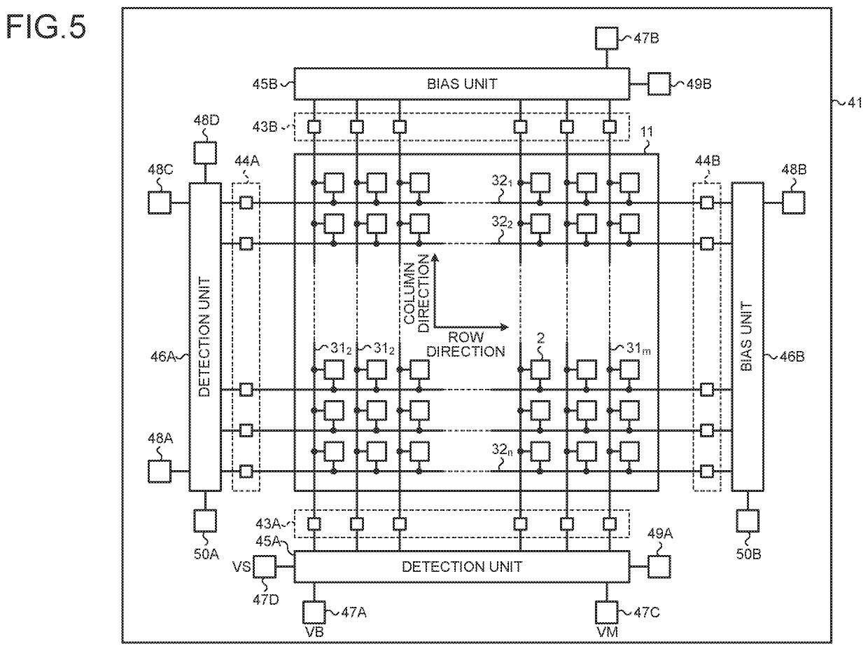

FIG. 5 is a diagram illustrating a specific configuration example of the first semiconductor substrate 41 of the imaging device to which the present disclosure can be applied. In the first semiconductor substrate 41, a first wire is formed to correspond to a first pixel row, and a second wire is formed to correspond to a second pixel row. Hereinafter, a wire formed to correspond to a pixel row is appropriately referred to as a row wire. Here, a first row wire formed to correspond to a pixel row refers to the control line 32₁ formed to correspond to a pixel row of the first row, and a second row wire formed to correspond to a pixel row refers to the control line 32ₙ formed to correspond to a pixel row of the nth row. A plurality of row wires indicated as the control lines 32₂ to 32ₙ₋₁ are present between the first row wire and the second row wire.

In addition, in the first semiconductor substrate 41, a first column wire is formed to correspond to a first pixel column, and a second column wire is formed to correspond to a second pixel column. Hereinafter, a wire formed to correspond to a pixel column is appropriately referred to as a column wire. A first column wire formed to correspond to a pixel column refers to the vertical signal line 31₁ formed to correspond to a pixel column of the first column, and a second column wire formed to correspond to a pixel column refers to the vertical signal line 31ₘ formed to correspond to a pixel column of the mth column. A plurality of column wires indicated as the vertical signal lines 31₂ to 31ₘ₋₁ are present between the first column wire and the second column wire.

As described also in FIG. 4, the first semiconductor substrate 41 is provided with connecting portions 43A and 43B and connecting portions 44A and 44B that connect the wires (the control lines 32₁ to 32ₙ and the vertical signal lines 31₁ to 31ₘ) formed on the first semiconductor substrate 41 and the pixel control unit formed on the second semiconductor substrate 42 that is a second substrate. Here, it is sufficient to provide either one of the connecting portions 43A and 43B in a case where a circuit of the pixel control unit to be connected is present only on one side in the vertical direction. For example, the vertical signal lines 31₁ to 31ₘ and the analog-to-digital conversion unit 14 are connected via the connecting portion 43A. Similarly, it is sufficient to provide either one of the connecting portions 44A and 44B in a case where a circuit of the pixel control unit to be connected is present only on one side in the horizontal direction. For example, the control lines 32₁ to 32ₙ and the row selection unit 12 are connected via the connecting portion 44A. Note that, hereinafter, in a case where there is no need to particularly distinguish the connecting portions 43A and 43B, the connecting portions 43A and 43B are collectively referred to as the connecting portions 43.

Furthermore, an inspection circuit 45A and a bias unit 45B corresponding to the inspection circuit 45A, and an inspection circuit 46A and a bias unit 46B corresponding to the inspection circuit 46A are provided on the first semiconductor substrate 41.

Furthermore, electrodes are provided on the first semiconductor substrate 41 in association with the inspection circuit 45A and the bias unit 45B and the inspection circuit 46A and the bias unit 46B. That is, the first semiconductor substrate 41 is provided with electrodes 47A, 47C, 47D, and 49A connected to the inspection circuit 45A. In addition, the first semiconductor substrate 41 is provided with electrodes 48A, 48C, 48D, and 50A connected to the inspection circuit 46A. In addition, the first semiconductor substrate 41 is provided with electrodes 49B and 47B connected to the bias unit 45B. Furthermore, the first semiconductor substrate 41 is provided with electrodes 48B and 50B connected to the bias unit 46B.

Each of the electrodes provided on the first semiconductor substrate 41 is a probe terminal used for inspection in a wafer state.

The bias unit 45B includes a bias circuit for applying a voltage to each of the vertical signal lines 31₁ to 31ₘ. The bias unit 45B applies a predetermined voltage to the electrode 49B to connect the electrode 49B and some or all of the vertical signal lines 31₁ to 31ₘ. The inspection circuit 45A for detecting the application of the voltage to the vertical signal lines 31₁ to 31ₘ is connected to far ends of the vertical signal lines 31₁ to 31ₘ with respect to the bias unit 45B. In the inspection circuit 45A, for example, a voltage of the electrode 47A can be monitored from the electrode 47C. In addition, in the inspection circuit 45A, a predetermined voltage is applied to electrode 49A to connect an electrode 49D and some or all of the vertical signal lines 31₁ to 31ₘ.

Similarly, the bias unit 46B for applying a voltage to each of the control lines 32₁ to 32ₙ and the inspection circuit 46A for detecting the application of the voltage to each of the control lines 32₁ to 32ₙ are connected to the control lines 32₁ to 32ₙ.

Note that the inspection circuits 45A and 46A and the bias units 45B and 46B arranged on the first semiconductor substrate 41 are not generally used after the first semiconductor substrate 41 and the second semiconductor substrate 42 are bonded and stacked.

As described above, in the imaging device 1 to which the present disclosure can be applied, a circuit including the inspection circuits 45A and 46A, the bias units 45B and 46B, and the electrodes 47A, 47B, 47C, 47D, 48A, 48B, 48C, 48D, 49A, 49B, 50A, and 50B is added, so that it is possible to implement the inspection of presence or absence of opening/short of the wires.

### <1.6 Configuration Example of Inspection Circuit>

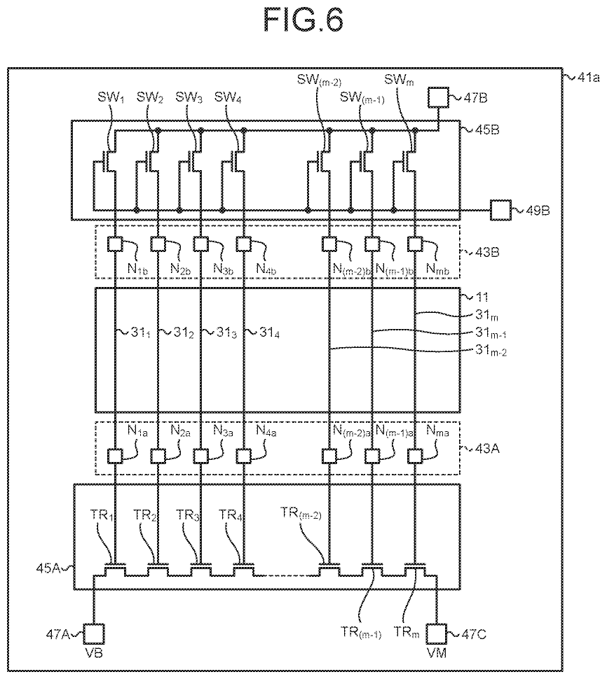

Next, a specific configuration example of the inspection circuit of the imaging device 1 to which the technology of the present disclosure can be applied will be described. FIG. 6 is a diagram illustrating a specific configuration example of a configuration of a first semiconductor substrate 41a of the imaging device 1 to which the technology of the present disclosure can be applied. Note that, in FIG. 6, the first semiconductor substrate 41a corresponding to the first semiconductor substrate 41 illustrated in FIG. 5 and the second semiconductor substrate 42 are stacked to constitute the imaging device 1. In addition, each of the pixels 2 included in the pixel array unit 11 and each of the control lines 32₁ to 32ₙ illustrated in FIG. 5 are omitted in FIG. 6. Similarly, in the configuration illustrated in FIG. 5, a configuration related to the pixel rows (configuration related to the respective control lines 32₁ to 32ₙ) is appropriately omitted in FIG. 6.

In FIG. 6, the connecting portion 43A includes connection nodes N₁ₐ, N₂ₐ, N₃ₐ, N₄ₐ, . . . , N₍ₘ₋₂₎ₐ, N₍ₘ₋₁₎ₐ, and Nₘₐ in a number corresponding to the number of columns (m) of the pixel array unit 11. Similarly, the connecting portion 43B includes connection nodes N_{1b}, N_{2b}, N_{3b}, N_{4b}, . . . , N_{(m-2)b}, N_{(m-1)b}, and N_{mb} in a number corresponding to the number of columns (m) of the pixel array unit 11.

One ends of the vertical signal lines 31₁ to 31ₘ are connected to the connection nodes N_{1b} to N_{mb} on a one-to-one basis. Similarly, the other ends of the vertical signal lines 31₁ to 31ₘ are connected to the connection nodes N₁ₐ to Nₘₐ on a one-to-one basis.

The first semiconductor substrate 41 and the second semiconductor substrate 42 are electrically connected by the connection nodes N₁ₐ to Nₘₐ or the connection nodes N_{1b} to N_{mb}.

The bias unit 45B includes, as a bias circuit, switch elements SW₁, SW₂, SW₃, SW₄, . . . , SW₍ₘ₋₂₎, SW₍ₘ₋₁₎, and SWₘ in a number corresponding to the number of columns (m) of the pixel array unit 11. Each of the switch elements SW₁ to SWₘ includes, for example, an NMOS transistor similarly to the pixel 2. The switch elements SW₁ to SWₘ have one ends (drains) commonly connected to the electrode 47B and the other ends (sources) connected to the one ends of the vertical signal lines 31₁ to 31ₘ on a one-to-one basis via the connection nodes N_{1b} to N_{mb}, respectively.

The electrode 49B is commonly connected to control ends (gates) of the switch elements SW₁ to SWₘ. When a high-level voltage (for example, 3 [V]) is applied to the electrode 49B, each of the switch elements SW_{1b} to SWₘ b is turned on (conductive), the electrode 47B is connected to each of the vertical signal lines 31₁ to 31ₘ, and the voltage applied to the electrode 47B is applied to each of the vertical signal lines 31₁ to 31ₘ. That is, each of the switch elements SW₁ to SWₘ can be considered as an output circuit that outputs a voltage to each of the vertical signal lines 31₁ to 31ₘ. Here, a voltage drop occurs at a threshold of each of the switch elements SW_{1b} to SWₘ b, but the influence of the voltage drop can be suppressed by increasing the voltage applied to the electrode 49B within a range allowed by a withstand voltage.

The inspection circuit 45A includes transfer elements TR₁, TR₂, TR₃, TR₄, . . . , TR₍ₘ₋₂₎ TR₍ₘ₋₁₎, and TRₘ in a number corresponding to the number of columns (m) of the pixel array unit 11. Each of the transfer elements TR₁ to TRₘ includes, for example, an NMOS transistor similarly to the pixel 2. The vertical signal lines 31₁ to 31ₘ are connected to gates of the transfer elements TR₁ to TRₘ on a one-to-one basis via the connection nodes N₁ₐ to Nₘₐ, respectively.

That is, each of the transfer elements TR₁ to TRₘ can be considered as an input circuit to which the voltage applied to each of the vertical signal lines 31₁ to 31ₘ is input. In addition, each of the transfer elements TR₁ to TRₘ has a function as a switch controlled to be conductive or non-conductive according to the voltage input (applied) to the gate.

In addition, the transfer elements TR₁ to TRₘ are connected in series, the electrode 47A is connected to one end of the series connection, and the electrode 47C is connected to the other end.

More specifically, among the transfer elements TR₁ to TRₘ, for example, a drain of the transfer element TR₁ arranged at a left end in FIG. 6 has a drain to which the electrode 47A is connected and a source connected to a drain of the transfer element TR₂ adjacent to the transfer element TR₁. A source of the transfer element TR₂ is connected to a drain of the transfer element TR₃ adjacent to the transfer element TR₂, and a source of the transfer element TR₃ is connected to a drain of the transfer element TR₄ adjacent to the transfer element TR₃. As described above, the source of each of the transfer elements TR₁ to TR₍ₘ₋₁₎ is sequentially connected to the drain of the adjacent transfer element. The source of the transfer element TR₍ₘ₋₁₎ is connected to the drain of the transfer element TRₘ arranged at a right end in FIG. 6, and the source of the transfer element TRₘ is connected to the electrode 47C.

With such a configuration, the electrode 47B is connected to the gate of each of the transfer elements TR₁ to TRₘ.

Hereinafter, as illustrated in FIG. 6, a mode in which each of transistors (the transfer elements TR₁ to TRₘ) is sequentially connected by a drain and source connection with an adjacent transistor is referred to as series connection. In the series connection, an output is determined by a logical product of states of gates with respect to application of a voltage to the gates of the transistors. That is, when at least one of the transistors connected in series is turned off (non-conductive), both ends of the series connection become non-conductive.

In addition, a mode in which a plurality of transistors are connected such that drains and sources of the respective transistors are commonly connected and gates of the respective transistors are independently connected is referred to as parallel connection. In the parallel connection, an output is determined by a logical sum of states of gates with respect to application of a voltage to the gates of the transistors. That is, when at least one of the transistors connected in parallel is turned on (conductive), both ends of the parallel connection (between the commonly connected sources and drains) become conductive.

### 1.7 Background

Next, the background leading to the creation of the embodiments of the present disclosure created by the present inventors will be described.

As described above, examples of a stacking scheme of a stacked chip include a scheme (WOW) of bonding a wafer and a wafer together and a scheme (COW) of bonding a wafer and a non-defective chip together. In the case of a stacked chip of the COW scheme, unlike the case of a stacked chip of the WOW scheme, the yield can be increased by selectively combining a non-defective product and a non-defective product.

Therefore, in order to sort the non-defective products before bonding, for example, the above-described inspection circuit and an inspection electrode electrically connected to the inspection circuit are provided on a wafer. Then, in an imaging device manufacturing stage, a probe tip of inspection equipment is brought into contact with the inspection electrode of the wafer to apply a voltage having a predetermined potential and measure a voltage, and the probe tip leaves a probe mark having irregularities on the inspection electrode.

When a non-defective product chip is bonded onto the inspection electrode having such a probe mark to form a stacked chip, since the probe mark has irregularities, the surface flatness of the wafer is impaired, which increases the probability that a bonding failure between the wafer and the chip occurs.

Therefore, the present inventors have created the embodiments of the present disclosure in view of such a circumstance. Specifically, since the wafer and the non-defective chip are bonded to each other in the case of the stacked chip of the COW scheme as described above, a non-bonded region where the chip is not bonded is present on the wafer side. Therefore, the present inventors have conceived to avoid the occurrence of the bonding failure between the wafer and the chip by providing the inspection electrode in the non-bonded region. That is, in the embodiments of the present disclosure, since the inspection electrode used for the non-defective product sorting of the wafer is provided in the non-bonded region with respect to the chip on the wafer, it is possible to avoid the occurrence of the bonding failure between the wafer and the chip due to the probe mark even when the probe mark caused by the inspection remains in the inspection electrode. Hereinafter, details of such embodiments of the present disclosure created by the present inventors will be sequentially described.

### 2. First Embodiment

### <2.1 Manufacturing Method>

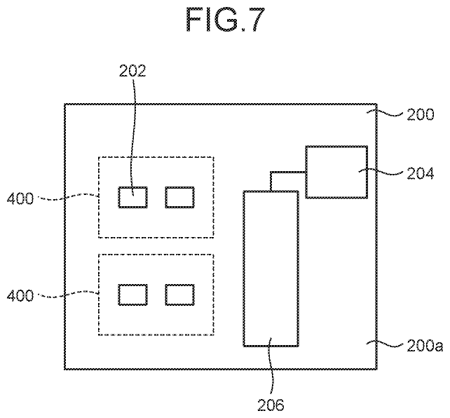

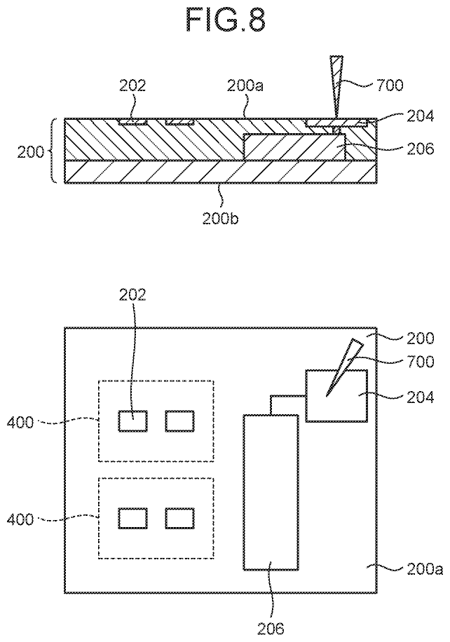

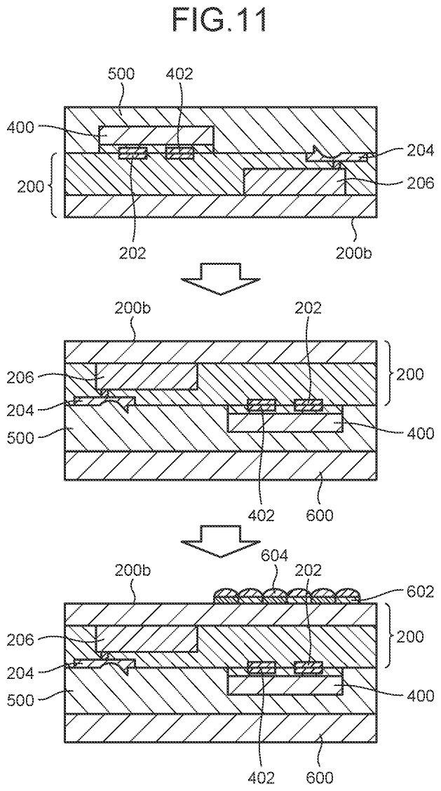

First, a manufacturing method of the imaging device 1 according to a first embodiment of the present disclosure will be described with reference to FIGS. 7 to 11. FIGS. 7 to 11 are explanatory views for describing the manufacturing method of the imaging device 1 according to the present embodiment. Specifically, FIG. 7 illustrates a plan view of a substrate 200 in a manufacturing process of the imaging device 1. In addition, a cross-sectional view of the substrate 200 in a manufacturing process of the imaging device 1 and a plan view corresponding to the cross-sectional view are illustrated on the lower side and the upper side, respectively, in FIGS. 8 to 10. In addition, FIG. 11 illustrates cross-sectional views of the imaging device 1 in manufacturing processes of the imaging device 1.

First, the substrate (first substrate) 200 formed of a wafer is fabricated as illustrated in FIG. 7. In the substrate 200, the pixel array unit 11 including a plurality of the pixels 2 two-dimensionally arranged in an array are provided on a surface (back surface 200b: see FIG. 8) side opposite to a front surface (surface facing a chip (second substrate) 400) 200a. In addition, as illustrated in FIG. 7, a plurality of bonding electrodes (first bonding electrodes) 202 for electrically and physically bonding the substrate 200 and the chip 400 are provided in a stack region (first stack region) on the front surface 200a where the chip 400 is to be stacked. In addition, for example, an inspection circuit 206 that detects a wiring failure (opening, short) or the like of an electronic circuit including the pixel array unit 11 is provided on the substrate 200. Furthermore, on the front surface 200a of the substrate 200, an inspection electrode 204 electrically connected to the inspection circuit 206 is provided in a region other than the stack region where the chip 400 is to be stacked.

In the present embodiment, the bonding electrodes 202 are preferably made of copper (Cu) having high conductivity in order to secure physical bonding and electrical connection with the chip 400. Furthermore, in the present embodiment, the inspection electrode 204 is also preferably made of copper since the number of processes can be reduced by simultaneously forming the inspection electrode 204 on the front surface 200a at the time of forming the bonding electrodes 202.

In addition, in the present embodiment, the inspection circuit 206 is not limited to the inspection circuit that detects the wiring failure (opening, short) or the like of the electronic circuit including the pixel array unit 11 as described above. In the present embodiment, it suffices that the inspection circuit 206 is an inspection circuit capable of inspecting a non-defective product and a defective product of the electronic circuit provided on the substrate 200 side.

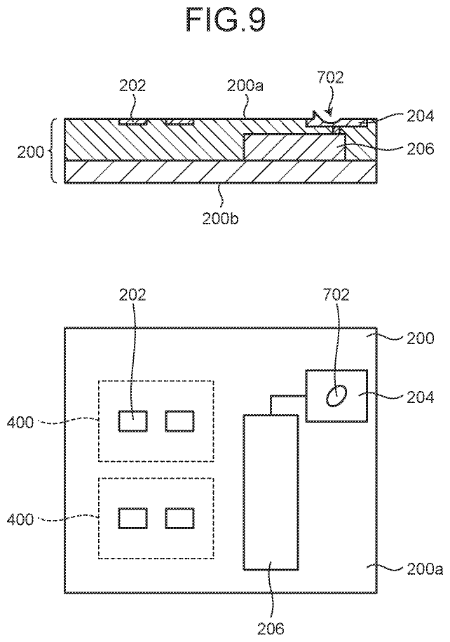

Next, as illustrated in FIG. 8, inspection is performed by bringing a probe tip 700 of inspection equipment into contact with the inspection electrode 204 provided on the front surface 200a of the substrate 200. At this time, as illustrated in FIG. 9, a probe mark 702 having irregularities remains on the inspection electrode 204 due to the contact of the probe tip 700. Specifically, the probe mark 702 includes a recess of the inspection electrode 204 generated by a press against the probe tip 700 and a protrusion that is a bulge of the inspection electrode 204 generated by the press against the probe tip 700.

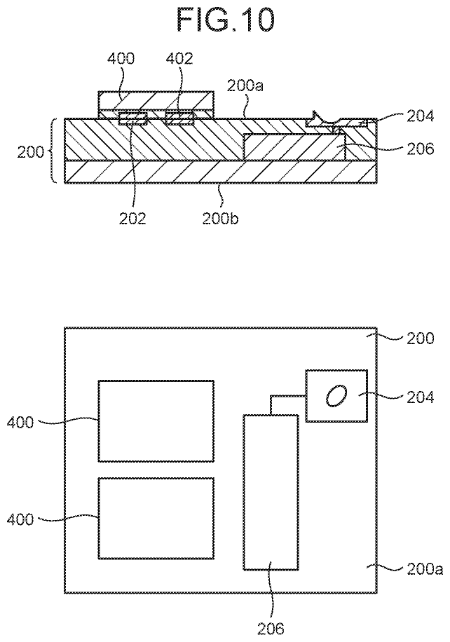

Next, the chip 400 to be stacked on the substrate 200 is prepared. The chip 400 has a smaller area than the substrate 200, and is provided with, for example, a logic circuit that controls the pixel array unit 11. Furthermore, a plurality of bonding electrodes (second bonding electrodes) 402 (see FIG. 10) for electrically and physically bonding the substrate 200 and the chip 400 are provided on a surface of the chip 400 facing the substrate 200. Specifically, the bonding electrodes 402 are bonded to the bonding electrodes 202, thereby electrically and physically bonding the substrate 200 and the chip 400. Therefore, the bonding electrodes 402 are preferably made of copper having high conductivity in order to secure physical bonding and electrical connection with the substrate 200.

Next, as illustrated in FIG. 10, the chip 400 is bonded to the stack region where the chip 400 is to be stacked, on the front surface 200a. At this time, the bonding electrodes 202 and the bonding electrodes 402 are bonded so that a relative position of the chip 400 with respect to the substrate 200 is accurately fixed at a predetermined position. As described above, in the present embodiment, the inspection electrode 204 is provided in a non-bonded region between the substrate 200 and the chip 400, and thus it is possible to avoid the occurrence of a bonding failure between the substrate 200 and the chip 400 caused by the probe mark 702 even when the probe mark 702 remains in the inspection electrode 204.

Next, as illustrated in the upper part of FIG. 11, an insulating film 500 is deposited on the front surface 200a of the substrate 200 so as to cover the chip 400, thereby planarizing the surface of the insulating film 500. The insulating film 500 can be made of, for example, an oxide film or a low dielectric material. Then, as illustrated in the middle part of FIG. 11, the substrate 200 is inverted, and a support substrate 600 is bonded to the planarized surface of the insulating film 500. Furthermore, as illustrated in the lower part of FIG. 11, a color filter 602, an on-chip lens 604, and the like are formed on the back surface 200b of the substrate 200.

### <2.2 Detailed Structure>

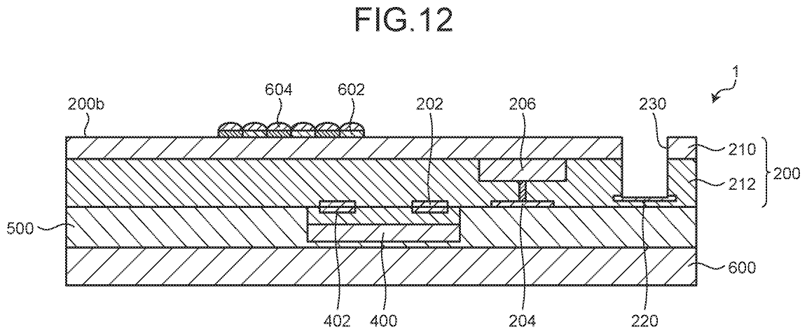

Next, a detailed structure of the imaging device 1 according to the present embodiment will be described with reference to FIG. 12. FIG. 12 is an explanatory view illustrating the imaging device 1 according to the present embodiment, and specifically illustrates a cross-sectional view of the imaging device 1.

As illustrated in FIG. 12, in the imaging device 1 according to the present embodiment, the substrate 200 includes a semiconductor layer 210 made of silicon or the like, and a wiring layer 212 stacked on the semiconductor layer 210 and including a wire made of, for example, aluminum (Al) or the like and an insulating film made of an oxide film or the like. Then, the wiring layer 212 faces the chip 400.

In addition, the pixel array unit 11 including the plurality of pixels 2 two-dimensionally arranged in an array is provided in the semiconductor layer 210 in the imaging device 1 according to the present embodiment as illustrated in FIG. 12. Furthermore, the color filter 602, the on-chip lens 604, and the like are provided on the back surface 200b of the semiconductor layer 210 so as to correspond to a position of the pixel array unit 11.

In addition, as illustrated in FIG. 12, the plurality of bonding electrodes 202 for electrically and physically bonding the substrate 200 and the chip 400 are provided on the wiring layer 212 in the stack region where the chip 400 having the smaller area than the substrate 200 is to be stacked. Furthermore, the wiring layer 212 of the substrate 200 includes the inspection circuit 206. In addition, the inspection electrode 204 electrically connected to the inspection circuit 206 is provided on the wiring layer 212 in a region other than the stack region where the chip 400 is to be stacked.

In addition, the chip 400 is provided with, for example, the logic circuit that controls the pixel array unit 11. Furthermore, the plurality of bonding electrodes 402 for electrically and physically bonding the substrate 200 and the chip 400 are provided on the surface of the chip 400 facing the substrate 200.

In addition, the bonding electrodes 202 and the bonding electrodes 402 are bonded so that the chip 400 is stacked and bonded on the wiring layer 212 as illustrated in FIG. 12. In addition, the insulating film 500 is provided on the wiring layer 212 so as to cover the chip 400. Then, the support substrate 600 is bonded onto the insulating film 500.

Furthermore, as illustrated in FIG. 12, an external connection electrode 220 is provided inside the wiring layer 212 in a thickness direction of the wiring layer 212 and in a region other than the stack region where the chip 400 is to be stacked. The external connection electrode 220 is an electrode for connecting the imaging device 1 to an external device. Furthermore, the substrate 200 has a trench 230 that exposes the external connection electrode 220 from the wiring layer 212 and the semiconductor layer 210.

In the present embodiment, the external connection electrode 220 is preferably made of the same material as that of the wire in the wiring layer 212, and is preferably made of, for example, aluminum. In this manner, since the external connection electrode 220 can be formed simultaneously with the wire in the wiring layer 212, an increase in the number of manufacturing processes of the imaging device 1 can be suppressed.

As described above, according to the present embodiment, the inspection electrode 204 is provided in the non-bonded region between the substrate 200 and the chip 400, and thus it is possible to avoid the occurrence of the bonding failure between the substrate 200 and the chip 400 caused by the probe mark 702 even when the probe mark 702 remains in the inspection electrode 204.

### 3. Second Embodiment

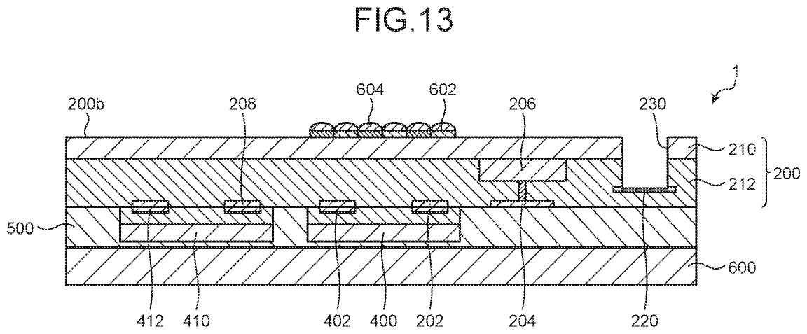

Next, a detailed structure of the imaging device 1 according to a second embodiment of the present disclosure will be described with reference to FIG. 13. FIG. 13 is an explanatory diagram illustrating the imaging device 1 according to the present embodiment, and specifically illustrates a cross-sectional view of the imaging device 1. Note that the description of points common to the embodiments described so far will be omitted here.

In the first embodiment described above, the single chip 400 is stacked on the substrate 200, but the embodiments of the present disclosure are not limited thereto, and a plurality of the chips 400 may be stacked on the substrate 200. Therefore, a second embodiment of the present disclosure in which the plurality of chips 400 are stacked on the substrate 200 will be described.

Specifically, as illustrated in FIG. 13, a chip (third substrate) 410 stacked on the substrate 200 has a smaller area than the substrate 200. The chip 410 may be provided with, for example, a memory unit (not illustrated) including a memory element.

In addition, similarly to the chip 400, the chip 410 is provided with a plurality of bonding electrodes (fourth bonding electrodes) 412 for electrically and physically bonding the substrate 200 and the chip 410 on a surface facing the substrate 200. Furthermore, on the front surface 200a of the substrate 200, a plurality of bonding electrodes (third bonding electrodes) 208 for electrically and physically bonding the substrate 200 and the chip 410 are provided in a stack region (second stack region) in which the chip 410 is to be stacked other than the stack region in which the chip 400 is to be stacked.

In the present embodiment, the bonding electrodes 208 and 412 are preferably made of copper having high conductivity in order to secure physical bonding and electrical connection between the substrate 200 and the chip 410. In this manner, since the bonding electrodes 208 can be formed simultaneously with the bonding electrodes 202 and the inspection electrode 204, an increase in the number of manufacturing processes of the imaging device 1 can be suppressed.

Furthermore, also in the present embodiment, the inspection electrode 204 is provided in a region other than the stack regions where the chips 400 and 410 are to be stacked on the front surface 200a of the substrate 200.

As described above, according to the present embodiment, the inspection electrode 204 is provided in a non-bonded region between the substrate 200 and each of the chips 400 and 410, and thus it is possible to avoid the occurrence of a bonding failure between the substrate 200 and each of the chips 400 and 410 caused by the probe mark 702 even when the probe mark 702 remains in the inspection electrode 204.

### 4. Third Embodiment

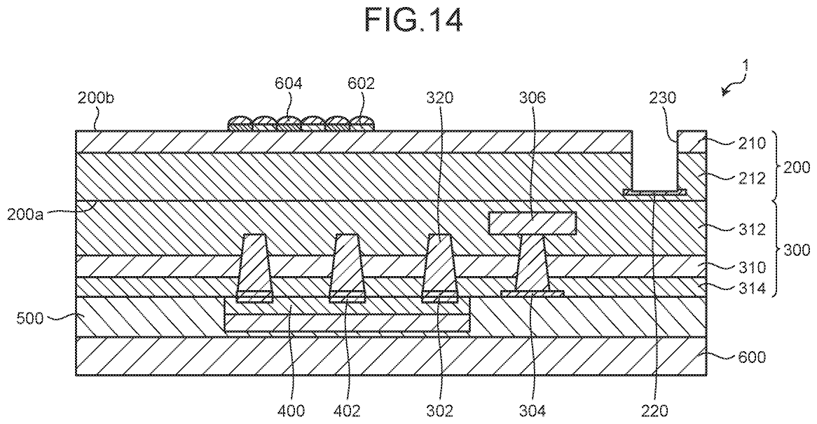

Next, a detailed structure of the imaging device 1 according to a third embodiment of the present disclosure will be described with reference to FIG. 14. FIG. 14 is an explanatory diagram illustrating the imaging device 1 according to the present embodiment, and specifically illustrates a cross-sectional view of the imaging device 1. Note that the description of points common to the embodiments described so far will be omitted here.

Although the imaging device 1 having the stacked structure of the substrate 200 and the chip 400 has been described in the first embodiment described above, the embodiments of the present disclosure are not limited thereto, and a stacked structure of a plurality of the substrates 200 stacked on each other and the chip 400 may be adopted. Therefore, a third embodiment of the present disclosure, which is the imaging device 1 having a scheme of bonding a wafer, a wafer, and a chip (WOWOC: wafer on wafer on chip) as a stacking scheme of a stacked chip, will be described.

As illustrated in FIG. 14, in the imaging device 1 according to the present embodiment, the substrate (first semiconductor substrate) 200 formed of a wafer and a substrate (second semiconductor substrate) 300 formed of a wafer are stacked on each other. The substrate 300 may be provided with, for example, a memory unit (not illustrated) including a memory element.

Similarly to the first embodiment, the substrate 200 includes the semiconductor layer 210 and the wiring layer 212 stacked on the semiconductor layer 210 and including a wire and an insulating film. Then, the pixel array unit 11 is provided in the semiconductor layer 210, and the color filter 602, the on-chip lens 604, and the like are provided on the back surface 200b of the semiconductor layer 210. Furthermore, as illustrated in FIG. 14, the external connection electrode 220 is provided inside the wiring layer 212 in a thickness direction of the wiring layer 212. In addition, the substrate 200 has the trench 230 that exposes the external connection electrode 220 from the wiring layer 212 and the semiconductor layer 210.

The substrate 300 stacked on the front surface 200a side of the substrate 200 includes a semiconductor layer 310 made of silicon and two wiring layers 312 and 314 stacked on two surfaces of the semiconductor layer 310. Each of the wiring layers 312 and 314 includes a wire and an insulating film. The wiring layer 312 on the substrate 200 side is provided with, for example, an inspection circuit 306 that detects a wiring failure (opening, short) or the like of an electronic circuit provided on the substrate 300. Note that the inspection circuit 306 may be electrically connected to an electronic circuit provided on the substrate 200 to detect a wiring failure (opening, short) or the like of the electronic circuit provided on the substrate 200.

In addition, as illustrated in FIG. 14, a plurality of bonding electrodes 302 for electrically and physically bonding the substrate 300 and the chip 400 are provided on the wiring layer 314 on the chip 400 side in a stack region where the chip 400 is to be stacked. In the present embodiment, the bonding electrodes 302 are preferably made of copper having high conductivity in order to secure physical bonding and electrical connection between the substrate 300 and the chip 410. Furthermore, on the wiring layer 314 on the chip 400 side, an inspection electrode 304 electrically connected to the inspection circuit 306 is provided in a region other than the stack region where the chip 400 is to be stacked. In the present embodiment, the inspection electrode 304 is preferably made of copper. In this manner, since the inspection electrode 304 can be formed simultaneously with the bonding electrodes 302, an increase in the number of manufacturing processes of the imaging device 1 can be suppressed.

Furthermore, as illustrated in FIG. 14, the substrate 300 includes through electrodes 320 each penetrating the wiring layer 314, the semiconductor layer 310, and the wiring layer 312. The through electrodes 320 are provided so as to be connected to the bonding electrodes 302, and electrically connects the chip 400 and the substrates 300 and 200 via the bonding electrodes 402 of the chip 400. Furthermore, the through electrode 320 is provided so as to be connected to the inspection electrode 304, and electrically connects the inspection electrode 304 and the inspection circuit 306.

As described above, according to the present embodiment, the inspection electrode 304 is provided in a non-bonded region between the substrate 300 and the chip 400, and thus it is possible to avoid the occurrence of a bonding failure between the substrate 300 and the chip 400 caused by the probe mark 702 even when the probe mark 702 remains in the inspection electrode 304.

### 5. Fourth Embodiment

Although the bonding electrodes 202 and the inspection electrode 204 are provided on the same surface (layer) in the first embodiment described above, the embodiments of the present disclosure are not limited thereto, and the bonding electrodes 202 and the inspection electrode 204 may be provided on different surfaces (layers). Therefore, a fourth embodiment of the present disclosure in which the bonding electrodes 202 and the inspection electrode 204 are provided on different surfaces will be described.

### <5.1 Manufacturing Method>

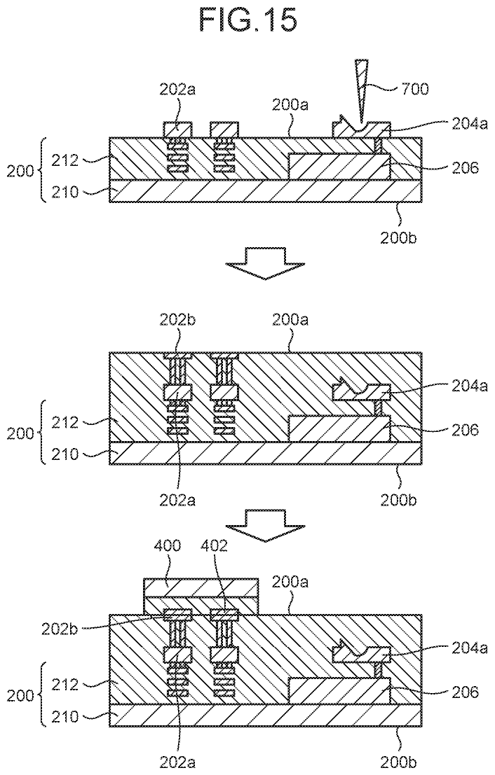

First, a manufacturing method of the imaging device 1 according to the present embodiment will be described with reference to FIG. 15. FIG. 15 is an explanatory view illustrating the manufacturing method of the imaging device 1 according to the present embodiment, and specifically illustrates cross-sectional views of the substrate 200 in manufacturing processes of the imaging device 1.

First, as illustrated in the upper part of FIG. 15, the substrate (first substrate) 200 formed of a wafer is fabricated similarly to each of the above-described embodiments. The substrate 200 is provided with the pixel array unit 11 on the back surface 200b side. In addition, the substrate 200 is provided with the inspection circuit 206.

Furthermore, as illustrated in the upper part of FIG. 15, a plurality of auxiliary electrodes 202a for electrically bonding the substrate 200 and the chip 400 are provided in a stack region on the front surface 200a where the chip 400 is to be stacked. Furthermore, on the front surface 200a of the substrate 200, an inspection electrode 204a electrically connected to the inspection circuit 206 is provided in a region other than the stack region where the chip 400 is to be stacked.

In the present embodiment, the auxiliary electrodes 202a and the inspection electrode 204a are preferably made of the same material as that of a wire in the wiring layer 212, and are preferably made of, for example, aluminum. In this manner, since the auxiliary electrodes 202a and the inspection electrode 204a can be formed simultaneously with the wire in the wiring layer 212, an increase in the number of manufacturing processes of the imaging device 1 can be suppressed.

Next, as illustrated in the upper part of FIG. 15, inspection is performed by bringing the probe tip 700 of inspection equipment into contact with the inspection electrode 204a provided on the front surface 200a of the substrate 200. At this time, a probe mark having irregularities remains on the inspection electrode 204a due to the contact of the probe tip 700.

Next, as illustrated in the middle part of FIG. 15, an insulating film is further deposited so as to fill the probe mark and cover the auxiliary electrodes 202a and the inspection electrode 204a, thereby planarizing the surface of the insulating film. Furthermore, a plurality of bonding electrodes 202b for electrically bonding the substrate 200 and the chip 400 are formed on the front surface 200a in the stack region where the chip 400 is to be stacked. The bonding electrodes 202b are electrically connected to the auxiliary electrodes 202a described above.

Next, as illustrated in the lower part of FIG. 15, the chip 400 is bonded to the stack region where the chip 400 is to be stacked on the front surface 200a. At this time, the bonding electrodes 202b and the bonding electrodes 402 are bonded so that a relative position of the chip 400 with respect to the substrate 200 is accurately fixed at a predetermined position.

As described above, in the present embodiment, the inspection electrode 204a is not provided on the surface on which the chip 400 is stacked, and thus it is possible to avoid the occurrence of a bonding failure between the substrate 200 and the chip 400 caused by the probe mark 702 even when the probe mark 702 remains in the inspection electrode 204a.

### <5.2 Detailed Structure>

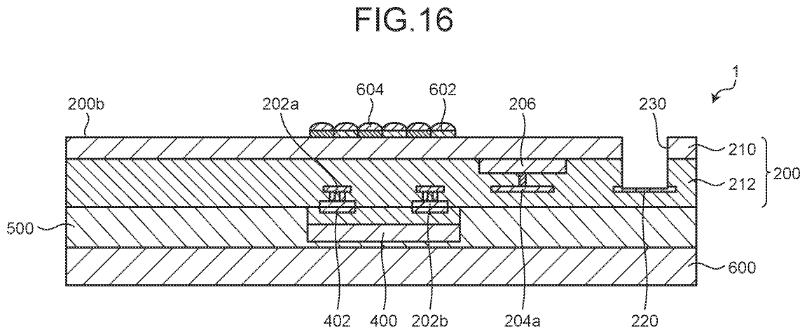

Next, a detailed structure of the imaging device 1 according to the present embodiment will be described with reference to FIG. 16. FIG. 16 is an explanatory view illustrating the imaging device 1 according to the present embodiment, and specifically illustrates a cross-sectional view of the imaging device 1. Note that the description of points common to the embodiments described so far will be omitted here.

As illustrated in FIG. 16, in the present embodiment, the bonding electrodes 202b and the inspection electrode 204a are provided at different heights in a thickness direction of the substrate 200. Specifically, the bonding electrodes 202b are provided on a surface of the wiring layer 212 of the substrate 200 facing the chip 400, and the inspection electrode 204a is provided inside the wiring layer 212 in a thickness direction of the wiring layer 212. More specifically, the inspection electrode 204a is covered with the insulating film.

In addition, in the present embodiment, the auxiliary electrodes 202a and the inspection electrode 204a are preferably located at the same height as the external connection electrode 220 in the thickness direction of the wiring layer 212. In this manner, since the auxiliary electrodes 202a and the inspection electrode 204a can be formed simultaneously with the external connection electrode 220, an increase in the number of manufacturing processes of the imaging device 1 can be suppressed.

As described above, according to the present embodiment, the inspection electrode 204a is not provided on the surface on which the chip 400 is stacked, and thus it is possible to avoid the occurrence of the bonding failure between the substrate 200 and the chip 400 caused by the probe mark 702 even when the probe mark 702 remains in the inspection electrode 204a. Furthermore, even if the surface flatness of the insulating film deposited on the inspection electrode 204a is impaired due to the probe mark 702 of the inspection electrode 204a, it is possible to avoid the occurrence of the bonding failure between the substrate 200 and the chip 400 since the inspection electrode 204a is not provided on the surface on which the chip 400 is stacked.

### 6. Summary

As described above, according to each of the embodiments of the present disclosure, the inspection electrode 204 is provided in the non-bonded region between the substrate 200 and the chip 400, and thus it is possible to avoid the occurrence of the bonding failure between the substrate 200 and the chip 400 caused by the probe mark 702 even when the probe mark 702 remains in the inspection electrode 204.

Note that an example in which the scheme (COW) of bonding a wafer and a chip together is applied has been described as each of the embodiments of the present disclosure described above, but the embodiments of the present disclosure are not limited thereto, and the scheme of bonding a chip and a chip together may be applied.

In addition, the imaging devices 1 according to the embodiments of the present disclosure can be manufactured by using methods, devices, and conditions used in manufacturing of general semiconductor devices. That is, the imaging devices 1 according to the present embodiments can be manufactured using existing semiconductor device manufacturing processes.

Note that examples of the above-described methods include a physical vapor deposition (PVD) method, a chemical vapor deposition (CVD) method, and an atomic layer deposition (ALD) method. Examples of the PVD method include a vacuum vapor deposition method, an electron beam (EB) vapor deposition method, various sputtering methods (magnetron sputtering method, radio frequency-direct current (RF-DC) coupled bias sputtering method, an electron cyclotron resonance (ECR) sputtering method, a facing target sputtering method, a high frequency sputtering method, and the like), an ion plating method, a laser ablation method, a molecular beam epitaxy (MBE) method, and a laser transfer method. In addition, examples of the CVD method include a plasma CVD method, a thermal CVD method, an organometallic (MO) CVD method, and a photo CVD method. Furthermore, examples of other methods include an electrolytic plating method, an electroless plating method, and a spin coating method; an immersion method; a cast method; a micro-contact printing method; a drop cast method; various printing methods such as a screen printing method, an inkjet printing method, an offset printing method, a gravure printing method, and a flexographic printing method; a stamping method; a spray method; and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendar coater method.

Furthermore, examples of a patterning method include chemical etching such as shadow mask, laser transfer, and photolithography, and physical etching using ultraviolet rays, laser, and the like. In addition, examples of a planarization technique include a chemical mechanical polishing (CMP) method, a laser planarization method, and a reflow method.

Note that an example of being applied to the imaging device 1 has been described as each of the embodiments of the present disclosure described above, but the embodiments of the present disclosure are not limited thereto, and may be applied to other semiconductor devices.

### 7. Application Examples

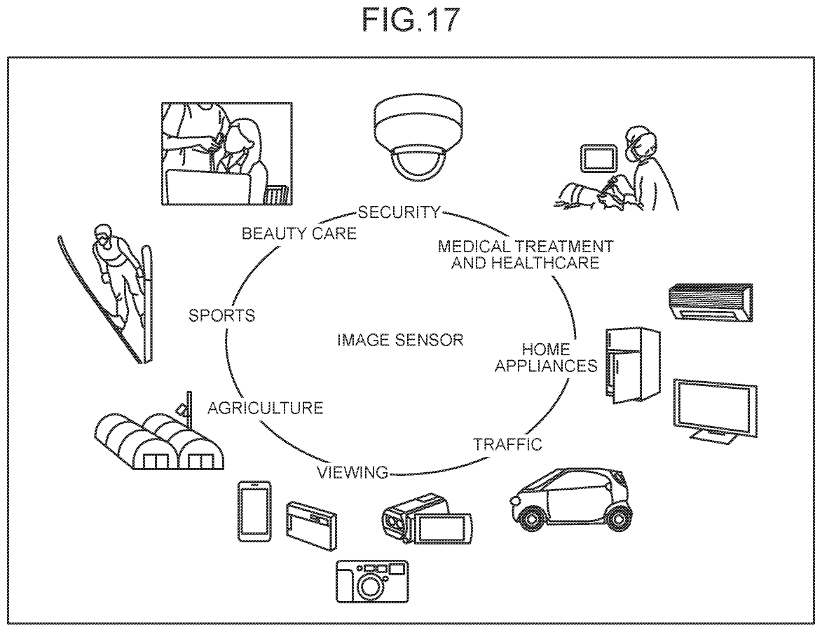

Next, application examples of the technology of the present disclosure will be described. FIG. 17 is a view illustrating application examples using each of the embodiments according to the technology of the present disclosure. The above-described imaging device 1 to which the technology of the present disclosure is applied can be used in various cases for sensing light such as visible light, infrared light, ultraviolet light, and X-rays as will be described below.
A device that captures an image used for viewing, such as a digital camera and a mobile device with a camera function.
A device used for traffic, such as in-vehicle sensors that capture the front, rear, surroundings, interior, and the like of an automobile in order for safe driving such as automatic stop and recognition of a driver's condition, a surveillance camera that monitors a traveling vehicle and a road, and a distance measurement sensor that measures a distance between vehicles.
A device used in home appliances, such as a TV, a refrigerator, and an air conditioner to capture a user's gesture and operate the device according to the gesture.
A device used for medical treatment and healthcare, such as an endoscope and a device that performs angiography by receiving infrared light.
A device used for security, such as a surveillance camera for crime prevention and a camera for personal authentication.
A device used for beauty care, such as a skin measuring device that captures a skin and a microscope that captures a scalp.
A device used for sports, such as an action camera and a wearable camera for sports applications.
A device used for agriculture, such as a camera for monitoring conditions of a field and a crop.

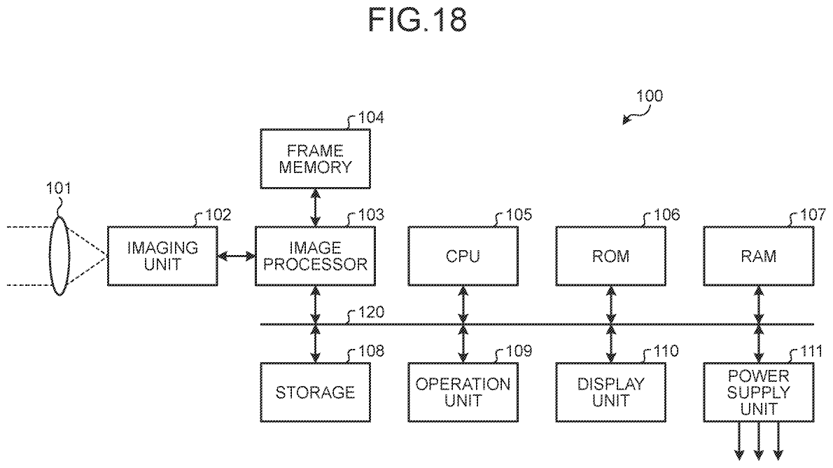

Next, an application example of the technology according to the present disclosure to a camera will be described. FIG. 18 is a block diagram illustrating a configuration of an example of a camera 100 to which the technology according to the present disclosure can be applied. In FIG. 18, the camera 100 includes an optical unit 101, an imaging unit 102, an image processor 103, a frame memory 104, a central processing unit (CPU) 105, a read only memory (ROM) 106, a random access memory (RAM) 107, a storage 108, an operation unit 109, a display unit 110, and a power supply unit 111. Among them, the image processor 103, the frame memory 104, the CPU 105, the ROM 106, the RAM 107, the storage 108, the operation unit 109, the display unit 110, and the power supply unit 111 are communicably connected to each other via a bus 120.

The storage 108 is a storage medium capable of storing data in a nonvolatile manner, and for example, a flash memory or a hard disk drive can be applied. The CPU 105 controls the overall operation of the camera 100 using the RAM 107 as a work memory according to a program stored in advance in the ROM 106 or the storage 108.

The operation unit 109 includes various operation means for a user to operate the camera 100, and passes a control signal corresponding to the user's operation to the CPU 105. The display unit 110 includes a display device using a liquid crystal display (LCD) or an organic electro-luminescence (EL), and a drive circuit that drives the display device. The display unit 110 causes the display device to display a screen corresponding to a display signal passed from the CPU 105 via the bus 120, for example. The power supply unit 111 supplies power to each unit of the camera 100.

The optical unit 101 includes one or more lenses and a mechanism such as a diaphragm and focus, and makes light from a subject incident on the imaging unit 102. The imaging unit 102 includes the pixels 2 according to the technology of the present disclosure, and the pixel array unit 11 is irradiated with light incident from the optical unit 101. In the pixel array unit 11, each of the pixels 2 outputs a pixel signal corresponding to the irradiated light. The imaging unit 102 supplies image data based on the pixel signal output from each of the pixels 2 to the image processor 103.

The image processor 103 includes, for example, a digital signal processor (DSP), and performs predetermined image processing such as white balance processing and gamma correction processing on the image data supplied from the imaging unit 102 using the frame memory 104. The image data subjected to the image processing by the image processor 103 is stored in the storage 108, for example.

When the imaging device 1 according to the technology of the present disclosure is applied to the imaging unit 102, a wire formed for each pixel row or each pixel column can be inspected with a minimum of additional circuits, so that an increase in the chip area can be suppressed. Therefore, the use of the imaging device 1 according to the technology of the present disclosure as the imaging unit 102 can contribute to further miniaturization of the camera 100. In addition, since the first semiconductor substrate 41 can be inspected alone, the yield of the imaging devices 1 can be improved, and cost of the camera 100 can be reduced.

### 8. Supplement

Although the preferred embodiments of the present disclosure have been described as above in detail with reference to the accompanying drawings, a technical scope of the present disclosure is not limited to such examples. It is apparent that a person who has ordinary knowledge in the technical field of the present disclosure can find various alterations and modifications within the scope of technical ideas described in the claims, and it should be understood that such alterations and modifications will naturally pertain to the technical scope of the present disclosure.

In addition, the effects described in the present specification are merely illustrative or exemplary, and are not limited. That is, the technology according to the present disclosure can exhibit other effects that are obvious to those skilled in the art from the description in the present specification, in addition to or instead of the above effects.

Note that the present technology can also have the following configurations.
(1) A solid-state imaging device comprising a stacked structure in which a first substrate and a second substrate having a smaller area than the first substrate are stacked,
   wherein the first substrate includes:
   an electronic circuit including an imaging element;
   an inspection circuit configured to inspect the electronic circuit;
   a first bonding electrode for electrical and physical bonding with the second substrate, the first bonding electrode being provided in a first stack region where the second substrate is to be stacked; and
   an inspection electrode provided in a region other than the first stack region and electrically connected to the inspection circuit, and
   the second substrate includes:
   a logic circuit that controls the imaging element; and
   a second bonding electrode for bonding with the first bonding electrode of the first substrate.
(2) The solid-state imaging device according to (1), wherein the first and second bonding electrodes are made of copper.
(3) The solid-state imaging device according to (1) or (2), wherein the first bonding electrode and the inspection electrode are provided on a surface of the first substrate facing the second substrate.
(4) The solid-state imaging device according to (3), wherein the inspection electrode is made of copper.
(5) The solid-state imaging device according to (1) or (2), wherein the first bonding electrode and the inspection electrode are provided at different heights in a thickness direction of the first substrate.
(6) The solid-state imaging device according to (5), wherein the inspection electrode is made of aluminum.
(7) The solid-state imaging device according to any one of (1) to (3), further comprising a third substrate having a smaller area than the first substrate and stacked on the first substrate,
   wherein the first substrate includes
   a third bonding electrode for electrical and physical bonding with the third substrate, the third bonding electrode being provided in a second stack region where the third substrate is to be stacked, the second stack region being located in a region other than the first stack region,
   the third substrate includes
   a fourth bonding electrode for bonding with the third bonding electrode of the first substrate, and
   the inspection electrode is provided in a region other than the second stack region.
(8) The solid-state imaging device according to (1) or (2), wherein
   the first substrate includes:
   a semiconductor layer; and
   a wiring layer provided on the semiconductor layer.
(9) The solid-state imaging device according to (8), wherein the first bonding electrode and the inspection electrode are provided on a surface of the wiring layer facing the second substrate.
(10) The solid-state imaging device according to (8), wherein
   the first bonding electrode is provided on a surface of the wiring layer facing the second substrate, and
   the inspection electrode is provided inside the wiring layer in a thickness direction of the wiring layer.
(11) The solid-state imaging device according to (10), wherein
   the first substrate includes:
   an external connection electrode provided inside the wiring layer in the thickness direction of the wiring layer in a region other than the first stack region; and
   a trench that exposes the external connection electrode from the wiring layer and the semiconductor layer.
(12) The solid-state imaging device according to (11), wherein
   the external connection electrode is located at an equal height to the inspection electrode in the thickness direction of the wiring layer.
(13) The solid-state imaging device according to (1) or (2), wherein
   the first substrate includes:
   a first semiconductor substrate including the imaging element; and
   a second semiconductor substrate stacked on the first semiconductor substrate,
   the first bonding electrode is provided on a surface of the second semiconductor substrate facing the second substrate, and
   the second substrate and the first semiconductor substrate are electrically connected via a through electrode penetrating the second semiconductor substrate.
(14) The solid-state imaging device according to (13), wherein
   the first semiconductor substrate includes the inspection circuit,
   the inspection electrode is provided on the surface of the second semiconductor substrate facing the second substrate, and
   the inspection electrode and the inspection circuit are electrically connected via the through electrode.
(15) The solid-state imaging device according to (13) or (14), wherein the second semiconductor substrate includes a memory element.
(16) The solid-state imaging device according to any one of (1) to (15), further comprising an insulating film that covers the second substrate stacked in the first stack region.
(17) The solid-state imaging device according to any one of (1) to (16), further comprising an on-chip lens provided on a surface, opposite to a surface facing the second substrate, of the first substrate.
(18) The solid-state imaging device according to any one of (1) to (17), wherein the first substrate includes a pixel array unit including a plurality of the imaging elements two-dimensionally arranged in an array.
(19) The solid-state imaging device according to any one of (1) to (18), wherein the inspection circuit is an inspection circuit that detects a wiring failure of the electronic circuit.
(20) A semiconductor device comprising a stacked structure in which a first substrate and a second substrate having a smaller area than the first substrate are stacked,
   wherein the first substrate includes:
   an electronic circuit;
   an inspection circuit configured to inspect the electronic circuit;
   a first bonding electrode for electrical and physical bonding with the second substrate, the first bonding electrode being provided in a first stack region where the second substrate is to be stacked; and
   an inspection electrode provided in a region other than the first stack region and electrically connected to the inspection circuit, and
   the second substrate includes a second bonding electrode for bonding with the first bonding electrode of the first substrate.

### REFERENCE SIGNS LIST

1 IMAGING DEVICE
2 PIXEL
11 PIXEL ARRAY UNIT
12 ROW SELECTION UNIT
13 CONSTANT CURRENT SOURCE UNIT
14 ANALOG-TO-DIGITAL CONVERSION UNIT
15 HORIZONTAL TRANSFER SCANNING UNIT
16 SIGNAL PROCESSING UNIT
17 TIMING CONTROL UNIT
18 HORIZONTAL TRANSFER LINE
19 REFERENCE SIGNAL GENERATION UNIT
21 PHOTODIODE
22 TRANSFER TRANSISTOR
23 RESET TRANSISTOR
24 AMPLIFICATION TRANSISTOR
25 SELECTION TRANSISTOR
31 VERTICAL SIGNAL LINE
32 CONTROL LINE
41, 41a FIRST SEMICONDUCTOR SUBSTRATE
42 SECOND SEMICONDUCTOR SUBSTRATE
43, 44 CONNECTING PORTION
45 INSPECTION CIRCUIT
46 BIAS UNIT
47, 48, 49, 50 ELECTRODE
100 CAMERA
101 OPTICAL UNIT
102 IMAGING UNIT
103 IMAGE PROCESSOR
104 FRAME MEMORY
105 CPU
106 ROM
107 RAM
108 STORAGE
109 OPERATION UNIT
110 DISPLAY UNIT
111 POWER SUPPLY UNIT
120 BUS
140 SINGLE-SLOPE ANALOG-TO-DIGITAL CONVERTER
141 COMPARATOR
142 COUNTER CIRCUIT
143 LATCH CIRCUIT
200, 300 SUBSTRATE
200a FRONT SURFACE
200b BACK SURFACE
202, 202b, 208, 302, 402, 412 BONDING ELECTRODE
202a AUXILIARY ELECTRODE
204, 204a, 304 INSPECTION ELECTRODE
206, 306 INSPECTION CIRCUIT
210, 310 SEMICONDUCTOR LAYER
212, 312, 314 WIRING LAYER
220 EXTERNAL CONNECTION ELECTRODE
230 TRENCH
320 THROUGH ELECTRODE
400, 410 CHIP
500 INSULATING FILM
600 SUPPORT SUBSTRATE
602 COLOR FILTER
604 ON-CHIP LENS
700 PROBE TIP
702 PROBE MARK

1. A solid-state imaging device comprising a stacked structure in which a first substrate and a second substrate having a smaller area than the first substrate are stacked,
wherein the first substrate includes:
an electronic circuit including an imaging element;
an inspection circuit configured to inspect the electronic circuit;
a first bonding electrode for electrical and physical bonding with the second substrate, the first bonding electrode being provided in a first stack region where the second substrate is to be stacked; and
an inspection electrode provided in a region other than the first stack region and electrically connected to the inspection circuit, and
the second substrate includes:
a logic circuit that controls the imaging element; and
a second bonding electrode for bonding with the first bonding electrode of the first substrate.

2. The solid-state imaging device according to claim 1, wherein the first and second bonding electrodes are made of copper.

3. The solid-state imaging device according to claim 1, wherein the first bonding electrode and the inspection electrode are provided on a surface of the first substrate facing the second substrate.

4. The solid-state imaging device according to claim 3, wherein the inspection electrode is made of copper.

5. The solid-state imaging device according to claim 1, wherein the first bonding electrode and the inspection electrode are provided at different heights in a thickness direction of the first substrate.

6. The solid-state imaging device according to claim 5, wherein the inspection electrode is made of aluminum.

7. The solid-state imaging device according to claim 1, further comprising a third substrate having a smaller area than the first substrate and stacked on the first substrate,
wherein the first substrate includes
a third bonding electrode for electrical and physical bonding with the third substrate, the third bonding electrode being provided in a second stack region where the third substrate is to be stacked, the second stack region being located in a region other than the first stack region,
the third substrate includes
a fourth bonding electrode for bonding with the third bonding electrode of the first substrate, and
the inspection electrode is provided in a region other than the second stack region.

8. The solid-state imaging device according to claim 1, wherein
the first substrate includes:
a semiconductor layer; and
a wiring layer provided on the semiconductor layer.

9. The solid-state imaging device according to claim 8, wherein the first bonding electrode and the inspection electrode are provided on a surface of the wiring layer facing the second substrate.

10. The solid-state imaging device according to claim 8, wherein
the first bonding electrode is provided on a surface of the wiring layer facing the second substrate, and
the inspection electrode is provided inside the wiring layer in a thickness direction of the wiring layer.

11. The solid-state imaging device according to claim 10, wherein
the first substrate includes:
an external connection electrode provided inside the wiring layer in the thickness direction of the wiring layer in a region other than the first stack region; and
a trench that exposes the external connection electrode from the wiring layer and the semiconductor layer.

12. The solid-state imaging device according to claim 11, wherein
the external connection electrode is located at an equal height to the inspection electrode in the thickness direction of the wiring layer.

13. The solid-state imaging device according to claim 1, wherein
the first substrate includes:
a first semiconductor substrate including the imaging element; and
a second semiconductor substrate stacked on the first semiconductor substrate,
the first bonding electrode is provided on a surface of the second semiconductor substrate facing the second substrate, and
the second substrate and the first semiconductor substrate are electrically connected via a through electrode penetrating the second semiconductor substrate.

14. The solid-state imaging device according to claim 13, wherein
the first semiconductor substrate includes the inspection circuit,
the inspection electrode is provided on the surface of the second semiconductor substrate facing the second substrate, and
the inspection electrode and the inspection circuit are electrically connected via the through electrode.

15. The solid-state imaging device according to claim 13, wherein the second semiconductor substrate includes a memory element.

16. The solid-state imaging device according to claim 1, further comprising an insulating film that covers the second substrate stacked in the first stack region.

17. The solid-state imaging device according to claim 1, further comprising an on-chip lens provided on a surface, opposite to a surface facing the second substrate, of the first substrate.

18. The solid-state imaging device according to claim 1, wherein the first substrate includes a pixel array unit including a plurality of the imaging elements two-dimensionally arranged in an array.

19. The solid-state imaging device according to claim 1, wherein the inspection circuit is an inspection circuit that detects a wiring failure of the electronic circuit.

20. A semiconductor device comprising a stacked structure in which a first substrate and a second substrate having a smaller area than the first substrate are stacked,
wherein the first substrate includes:
an electronic circuit;
an inspection circuit configured to inspect the electronic circuit;
a first bonding electrode for electrical and physical bonding with the second substrate, the first bonding electrode being provided in a first stack region where the second substrate is to be stacked; and
an inspection electrode provided in a region other than the first stack region and electrically connected to the inspection circuit, and
the second substrate includes a second bonding electrode for bonding with the first bonding electrode of the first substrate.
